(19) United States
(12) Patent Application Publication
(10) Pub. No.: US 2024/0321937 A1
(43) Pub. Date: Sep. 26, 2024

(54) METHOD OF MANUFACTURING SEMICONDUCTOR DEVICE HAVING CAPACITOR PILLAR

(71) Applicant: MICRON TECHNOLOGY, INC., BOISE, ID (US)

(72) Inventor: Keisuke Otsuka, Kasaoka (JP)

(73) Assignee: MICRON TECHNOLOGY, INC., Boise, ID (US)

(21) Appl. No.: 18/588,454

(22) Filed: Feb. 27, 2024

Related U.S. Application Data
(60) Provisional application No. 63/492,108, filed on Mar. 24, 2023.

(51) Int. Cl. H01G 4/30; H01L 21/311

(52) U.S. Cl. CPC H01L 28/40; H01L 21/31116; H01L 21/31144

(57) ABSTRACT

A method that includes, forming a first insulating film, first etching the first insulating film to form a first cylinder having a first diameter, forming a second insulating film on the first insulating film, second etching the second insulating film to form a second cylinder overlapping the first cylinder and having a second diameter different from the first diameter, third etching the first insulating film overlapping the second cylinder, filling the first and second cylinders with a conductive material, and removing the first and second insulating films.

### CROSS-REFERENCE TO RELATED APPLICATION(S)

This application claims priority to U.S. Provisional Application No. 63/492,108, filed on Mar. 24, 2023. The aforementioned application is incorporated herein by reference, in its entirety, for any purpose.

### BACKGROUND

A semiconductor device such as a DRAM has pillar-shaped cell capacitors. In order to ensure a sufficient capacitance of each cell capacitor, the pillar height needs to be raised. In order to form such a high capacitor pillar, a cylinder with a large aspect ratio has to be formed in a thick insulating film; however, formation of such a cylinder is not easy.

### BRIEF DESCRIPTION OF THE DRAWINGS

FIG. 1 is a schematic cross-sectional view showing a configuration of a main part of a semiconductor device according to one embodiment of the present disclosure;

FIGS. 2A to 2M are process diagrams for explaining a manufacturing method of a semiconductor device according to a first embodiment of the present disclosure;

FIG. 3A is a schematic cross-sectional view showing a state where misalignment has not occurred in an upper and lower cylinders in the first embodiment;

FIG. 3B is a schematic cross-sectional view showing a state where misalignment has occurred in the upper and lower cylinders in the first embodiment;

FIGS. 4A to 4K are process diagrams for explaining a manufacturing method of a semiconductor device according to a second embodiment of the present disclosure;

FIG. 5A is a schematic cross-sectional view showing a state where misalignment has not occurred in an upper and lower cylinders in the second embodiment;

FIG. 5B is a schematic cross-sectional view showing a state where misalignment has occurred in the upper and lower cylinders in the second embodiment;

FIG. 6 is a schematic cross-sectional view showing a configuration of a main part of a semiconductor device according to another embodiment of the present disclosure; and

FIGS. 7A to 7D are process diagrams for explaining a manufacturing method of a semiconductor device according to a third embodiment of the present disclosure.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

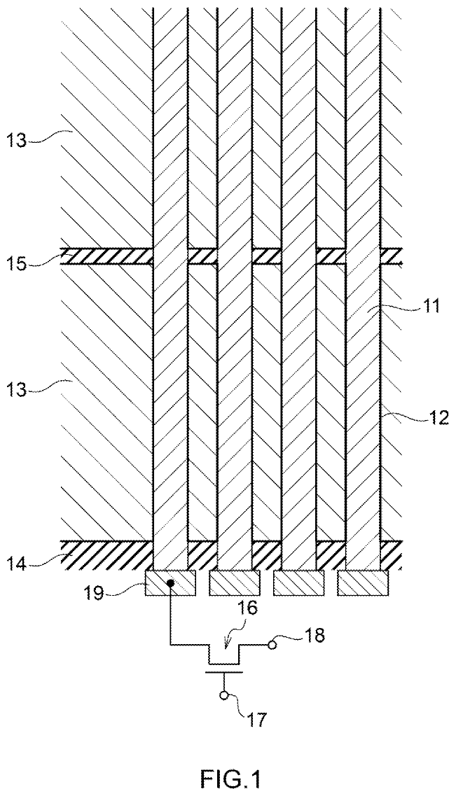

FIG. 1 is a schematic cross-sectional view showing a configuration of a main part of a semiconductor device according to one embodiment of the present disclosure. The semiconductor device shown in FIG. 1 includes a plurality of capacitor pillars 11, a capacitor dielectric film 12 covering the surface of each capacitor pillar 11, and a counter electrode 13 covering each capacitor pillar 11 via the capacitor dielectric film 12. A lower portion of the capacitor pillar 11 penetrates through an insulating film 14 made of, for example, silicon nitride and is connected to a pad electrode 19 made of, for example, tungsten. The pad electrode 19 is connected to a cell transistor 16. A gate electrode of the cell transistor 16 is connected to a word line 17. Accordingly, when the word line 17 becomes active, the capacitor pillar 11 is connected to a bit line 18 via the cell transistor 16. Further, a beam 15 made of, for example, silicon nitride is provided at a predetermined position in the height direction of the capacitor pillar 11, with which the capacitor pillar 11 having a large aspect ratio is supported. The diameter of the capacitor pillar 11 is substantially constant or becomes slightly smaller in the depth direction. In the latter case, change of the diameter is continuous, and there is no portion where the diameter changes discontinuously.

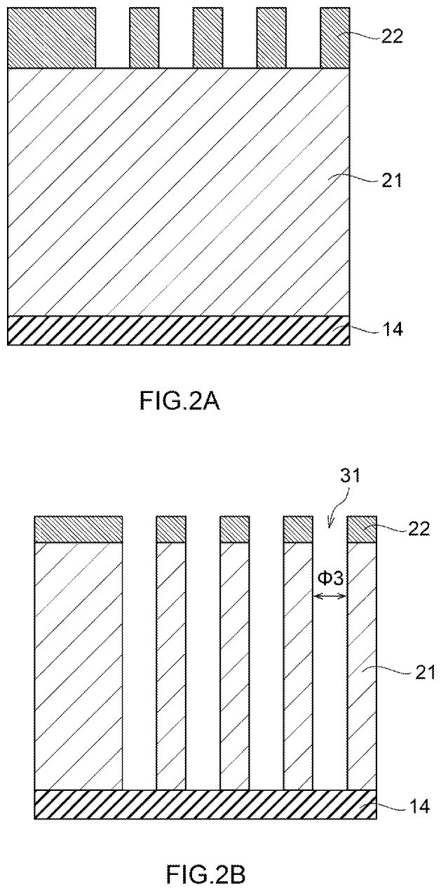

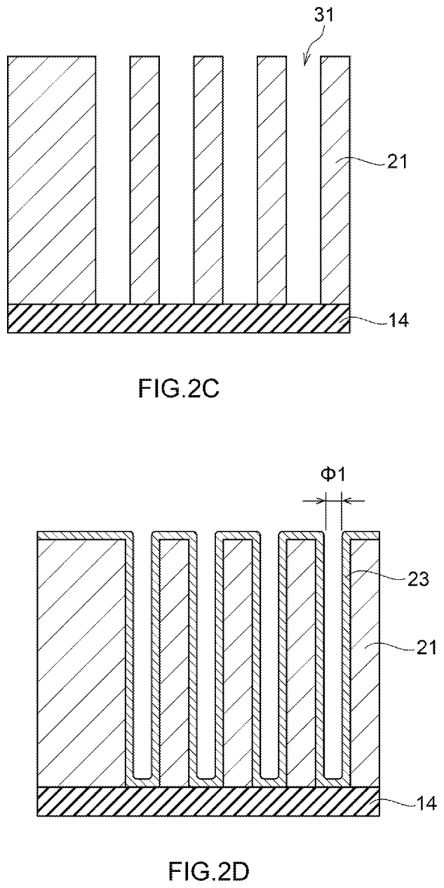

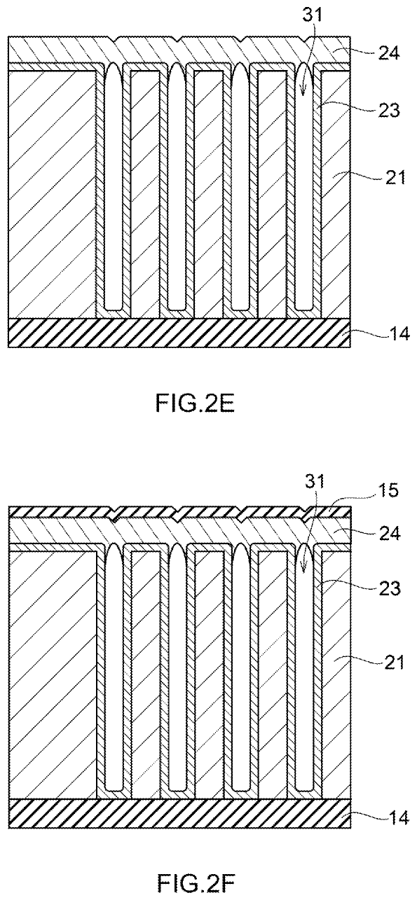

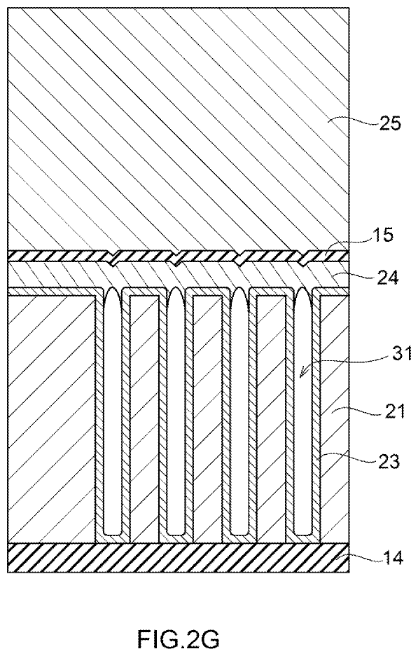

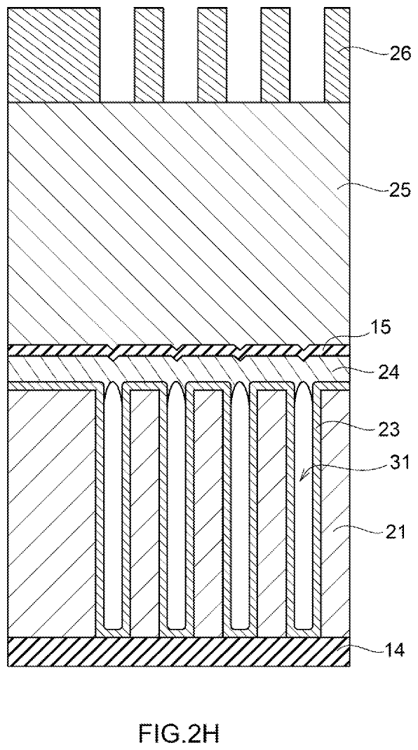

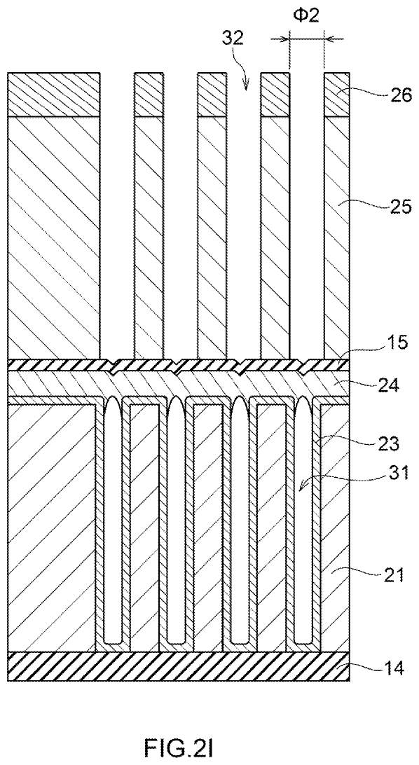

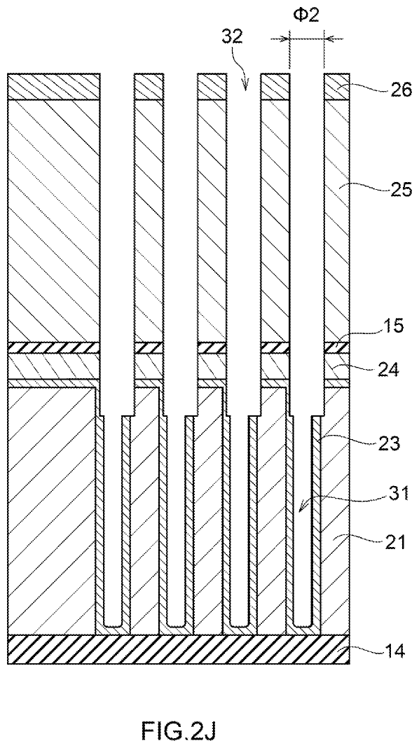

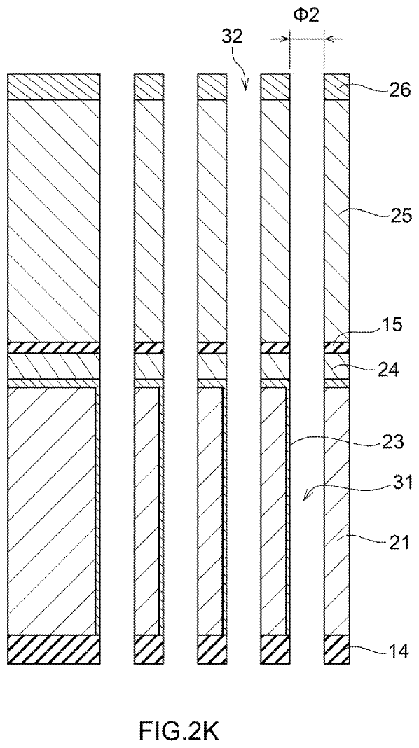

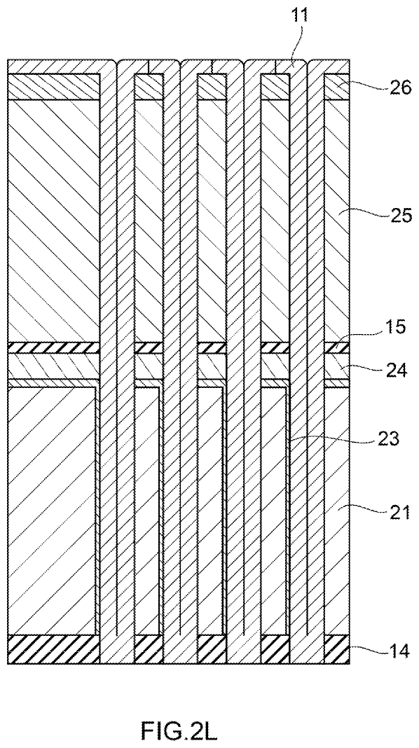

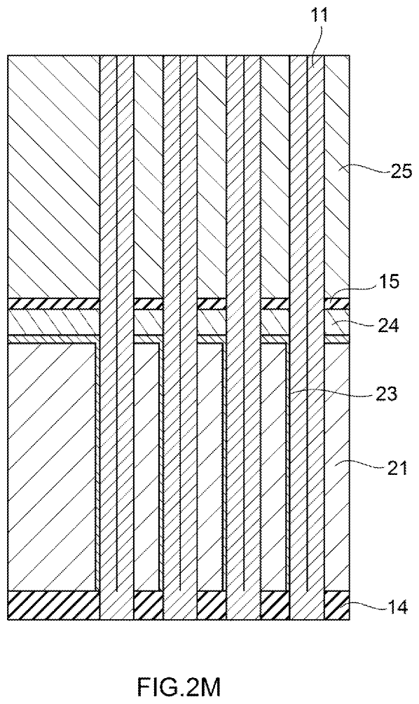

FIGS. 2A to 2M are process diagrams for explaining a manufacturing method of a semiconductor device according to the first embodiment of the present disclosure.

First, as shown in FIG. 2A, a thick insulating film 21 made of, for example, silicon oxide is formed on the insulating film 14 made of, for example, silicon nitride, and a hard mask 22 is formed on the surface of the insulating film 21. BPSG or TEOS can be used as a material of the insulating film 21. Polysilicon or carbon can be used as a material of the hard mask 22. Next, as shown in FIG. 2B, the insulating film 21 is etched through the hard mask 22, so that a cylinder 31 is formed in the insulating film 21. In formation of the cylinder 31, the insulating film 14 serves as an etching stopper. At this time, the diameter of the cylinder 31 is φ3. The diameter φ3 may be the same as the target diameter of the capacitor pillar 11.

Next, the hard mask 22 is removed as shown in FIG. 2C, and then a thin insulating film 23 made of, for example, silicon oxide is formed on the entire surface as shown in FIG. 2D. The insulating film 23 is deposited by a method excellent in coverage, such as CVD. In this manner, the insulating film 23 is formed not only on the top surface of the insulating film 21 but also on the inner wall of the cylinder 31. As a result, the diameter of the cylinder 31 is reduced to φ1. As a material of the insulating film 23, silicon oxide that is the same as the material of the insulating film 21 can be used. However, a deposition condition is adjusted so as to make the etching rate of the insulating film 23 in etching described later higher than that of the insulating film 21. For example, in a case of forming the insulating film 23 made of silicon oxide by CVD, the deposition temperature may be set to a lower temperature than usual, whereby the film quality is lowered. Alternatively, SiON may be used as the material of the insulating film 23. SiON is higher than the insulating film 21 made of silicon oxide in etching rate.

Next, as shown in FIG. 2E, an insulating film 24 made of, for example, silicon oxide is formed. By using a TEOS oxide film with low coverage as a material of the insulating film 24, it is possible to close the upper portion of the cylinder 31 without completely filling the cylinder 31 therewith. Next, as shown in FIG. 2F, the insulating film 15 made of, for example, silicon nitride, which will be turned into the beam 15 later, is formed on the surface of the insulating film 24. At this time, since the upper portion of the cylinder 31 is closed with the insulating film 24, the insulating film 15 is not deposited inside the cylinder 31. Next, a thick insulating film 25 made of, for example, silicon oxide is formed on the insulating film 15, as shown in FIG. 2G, and a hard mask 26 is formed on the surface of the insulating film 25, as shown in FIG. 2H. BPSG or TEOS can be used as a material of the insulating film 25. Polysilicon or carbon can be used as a material of the hard mask 26. Next, as shown in FIG. 2I, the insulating film 25 is etched through the hard mask 26, whereby a cylinder 32 is formed in the insulating film 25. In formation of the cylinder 32, the insulating film 15 serves as an etching stopper. The diameter of the cylinder 32 is φ2. The diameter φ2 may be the same as the target diameter of the capacitor pillar 11. The diameter φ2 of the cylinder 32 is greater than the diameter 1 of the cylinder 31. Accordingly, even if misalignment occurs, a state where the entire cylinder 31 overlaps the cylinder 32 in plan view is obtained.

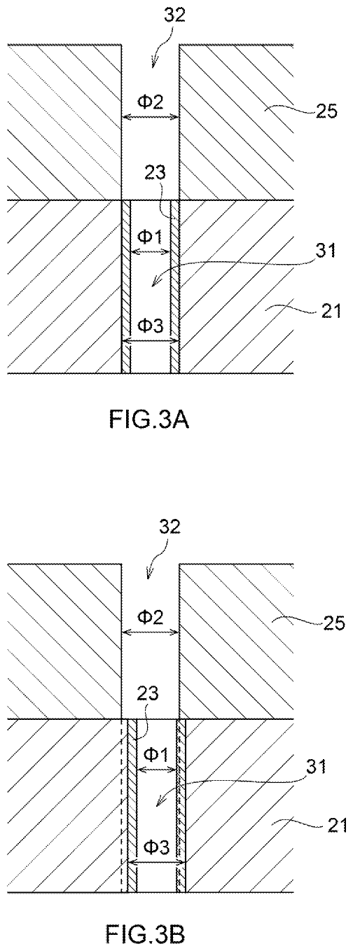

Subsequently, as shown in FIG. 2J, by changing the etching condition, the insulating film 15 made of, for example, silicon nitride is etched. Etching is further performed, so that the diameter of the cylinder 31 is increased to φ2, as shown in FIG. 2K. Here, in a case where the original diameter φ3 of the cylinder 31 and the diameter φ2 of the cylinder 32 are the same as each other as shown in FIG. 3A that is a schematic diagram, what is removed by etching shown in FIG. 2K is the insulating film 23 forming the inner wall of the cylinder 31. As described above, although the insulating films 21 and 23 are both made of silicon oxide, the insulating film 23 is higher than the insulating film 21 in etching rate. Therefore, the insulating film 23 located at a deeper position can be easily etched. Also, in a case where the insulating film 23 is made of SiON, the etching rate is higher in the insulating film 23 than in the insulating film 21, and therefore the insulating film 23 located at a deeper position can be easily etched. Even when misalignment has occurred in formation of the cylinder 32 as shown in FIG. 3B, what is mostly removed by etching is the insulating film 23 that can be easily etched, as shown with a broken line, and the amount of the insulating film 21 to be etched is small. Therefore, even when misalignment has occurred in formation of the cylinder 32, the diameter of the cylinder 31 can be increased to φ2, that is, substantially the same diameter as the target diameter of the capacitor pillar 11.

Next, after the hard mask 26 is removed, a conductive material made of, for example, titanium nitride is deposited on the entire surface, as shown in FIG. 2L, so that the capacitor pillar 11 is embedded in the cylinders 31 and 32. At this time, the lower portion of the capacitor pillar 11 is connected to the pad electrode 19 shown in FIG. 1. Next, as shown in FIG. 2M, an unnecessary portion of titanium nitride formed on the top surface of the insulating film 25 is etched back, whereby the capacitor pillars 11 are electrically isolated from each other. All the insulating films 21 and 23 to 25 made of silicon oxide are then removed, whereby a space is formed between the capacitor pillars 11. Thereafter, the capacitor dielectric film 12 is formed on the surface of the capacitor pillar 11, and the space is filled with the counter electrode 13. The semiconductor device shown in FIG. 1 is completed in this manner.

As described above, in the first embodiment, the cylinder 31 having a diameter of φ1 (<φ2) and the cylinder 32 having a diameter of φ2 are overlapped each other, and the diameter of the cylinder 31 is increased via the cylinder 32. Accordingly, the cylinders 31 and 32 having a large aspect ratio as a whole can be formed easily. Further, instead of embedding the capacitor pillar 11 made of, for example, titanium nitride in each of the cylinders 31 and 32, the cylinders 31 and 32 are formed, and thereafter the capacitor pillar 11 made of, for example, titanium nitride is embedded therein at once. Accordingly, no interface is formed in the capacitor pillar 11 at the boundary between the cylinder 31 and the cylinder 32. Therefore, increase in a resistance value due to the presence of the interface does not occur.

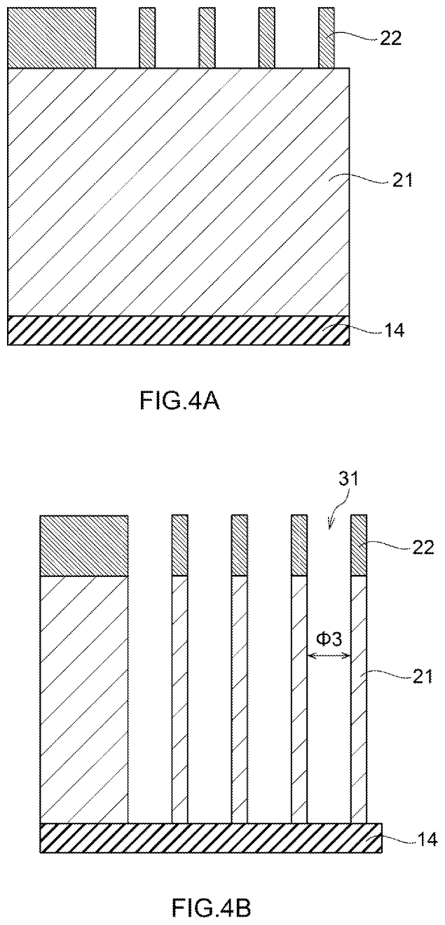

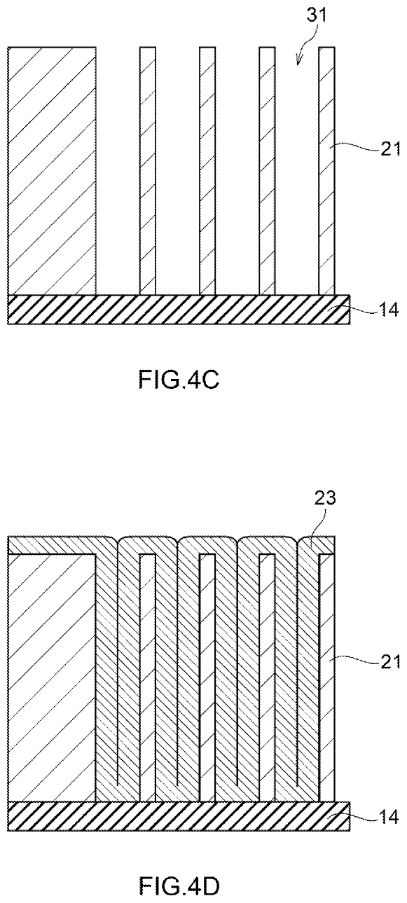

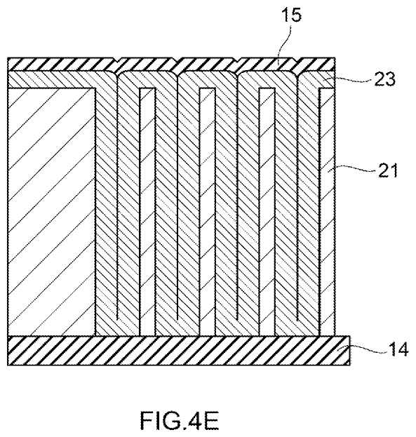

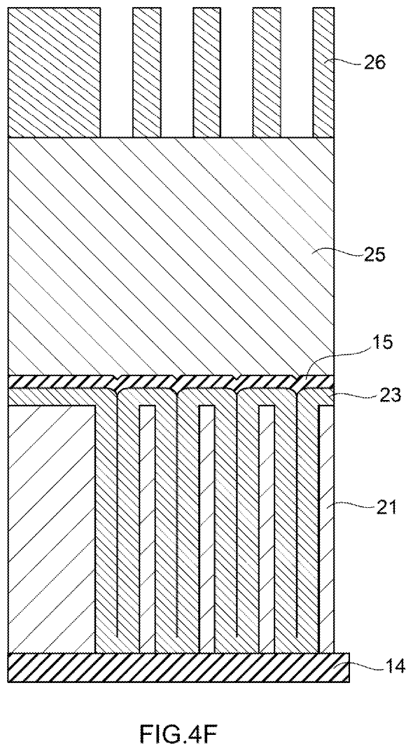

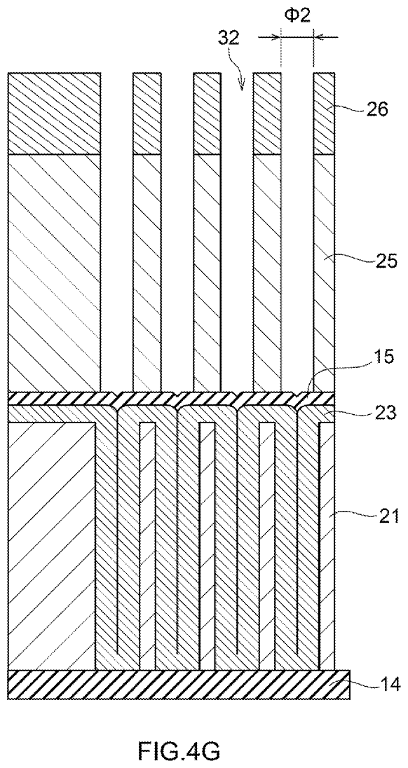

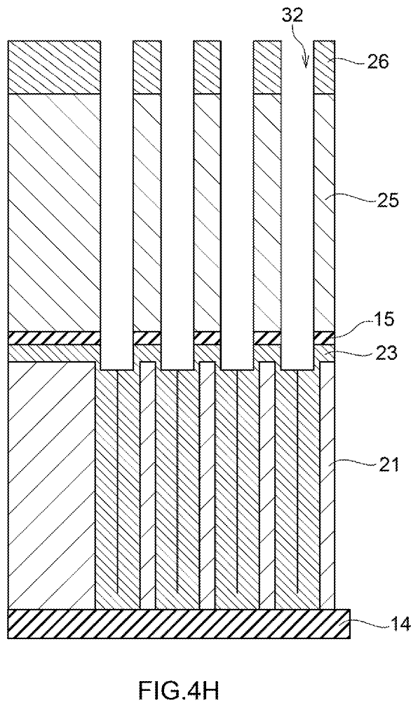

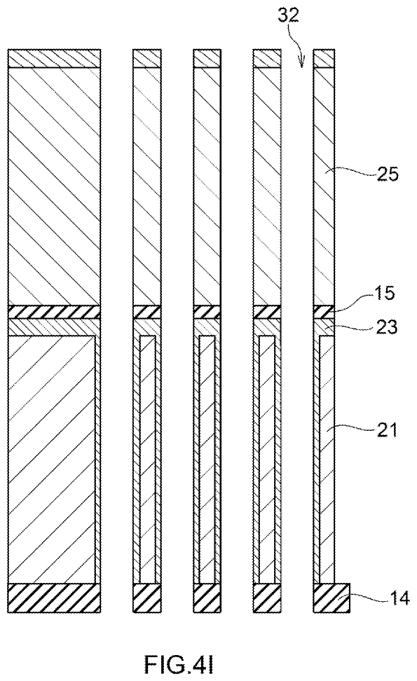

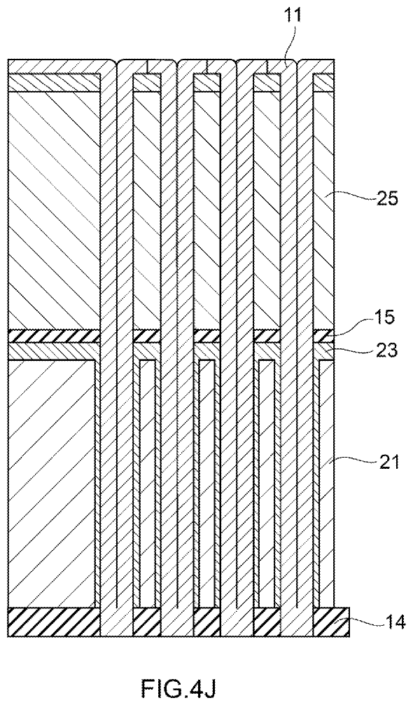

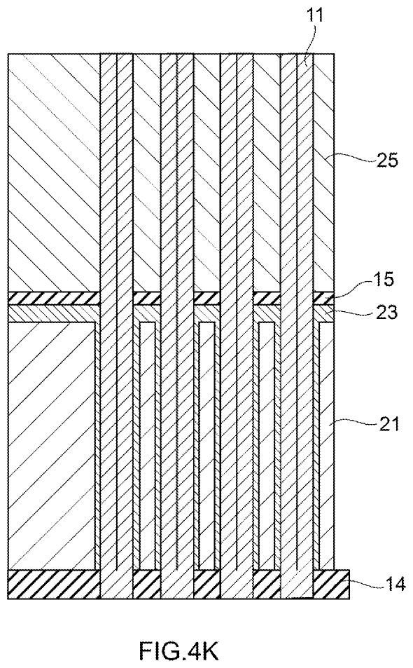

FIGS. 4A to 4K are process diagrams for explaining a manufacturing method of a semiconductor device according to a second embodiment of the present disclosure.

First, as shown in FIG. 4A, the thick insulating film 21 made of, for example, silicon oxide is formed on the insulating film 14 made of, for example, silicon nitride, and the hard mask 22 is formed on the surface of the insulating film 21. BPSG or TEOS can be used as a material of the insulating film 21. Polysilicon or carbon can be used as a material of the hard mask 22. Next, as shown in FIG. 4B, the insulating film 21 is etched through the hard mask 22, so that the cylinder 31 is formed in the insulating film 21. In formation of the cylinder 31, the insulating film 14 serves as an etching stopper. The diameter of the cylinder 31 is φ3. The diameter φ3 is greater than the target diameter of the capacitor pillar 11.

Next, the hard mask 22 is removed as shown in FIG. 4C, and thereafter the insulating film 23 made of, for example, silicon oxide is formed on the entire surface, so that the cylinder 31 is filled therewith, as shown in FIG. 4D. Although silicon oxide can be used as a material of the insulating film 23, a deposition condition is adjusted in such a manner that its etching rate in etching described later is higher than that of the insulating film 21. Alternatively, polysilicon, carbon, or SiON, for example, may be used as the material of the insulating film 23.

Next, as shown in FIG. 4E, the insulating film 15 made of, for example, silicon nitride is formed on the surface of the insulating film 23. Subsequently, as shown in FIG. 4F, the thick insulating film 25 made of, for example, silicon oxide is formed on the insulating film 15, and thereafter the hard mask 26 is formed on the surface of the insulating film 25. BPSG or TEOS can be used as a material of the insulating film 25. Polysilicon or carbon can be used as a material of the hard mask 26. Next, as shown in FIG. 4G, the insulating film 25 is etched through the hard mask 26, whereby the cylinder 32 is formed in the insulating film 25. In formation of the cylinder 32, the insulating film 15 serves as an etching stopper. The diameter of the cylinder 32 is φ2. The diameter φ2 may be the same as the target diameter of the capacitor pillar 11. The diameter φ2 of the cylinder 32 is smaller than the diameter φ3 of the cylinder 31. Accordingly, even when misalignment has occurred, a state where the entire cylinder 32 overlaps the cylinder 31 in plan view is obtained.

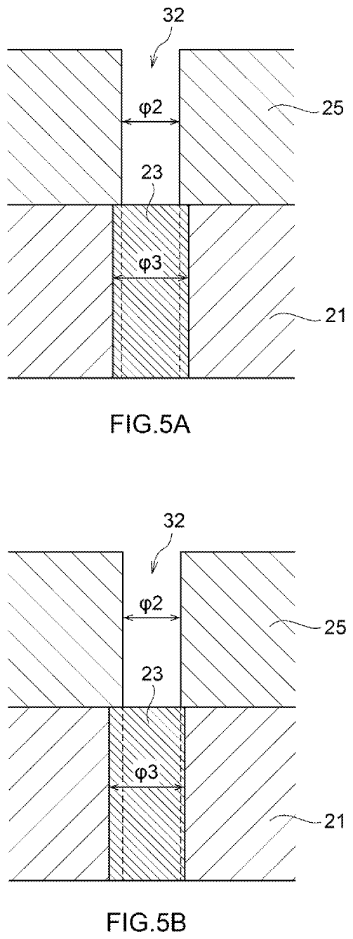

Next, as shown in FIG. 4H, by changing the etching condition, the insulating film 15 made of, for example, silicon nitride is etched. Etching is further performed, so that the insulating film 23 embedded in the cylinder 31 is etched, as shown in FIG. 4I. Here, since the diameter φ3 of the cylinder 31 is greater than the diameter φ2 of the cylinder 32 as shown in FIG. 5A that is a schematic diagram, what is removed by etching shown in FIG. 4I is the insulating film 23 embedded in the cylinder 31 as shown with a broken line. As described above, although the insulating films 21 and 23 are both made of silicon oxide, the etching rate is higher in the insulating film 23 than in the insulating film 21. Therefore, the insulating film 23 located at a deeper position can be etched easily. Furthermore, even when misalignment has occurred in formation of the cylinder 32 as shown in FIG. 5B, the insulating film 21 does not need to be etched or the amount of the insulating film 21 to be etched is small, because the diameter φ3 of the cylinder 31 is greater than the diameter φ2 of the cylinder 32. Therefore, even when misalignment has occurred in formation of the cylinder 32, it is possible to form a cylinder having the diameter φ2 substantially the same as the target diameter of the capacitor pillar 11 in the insulating film 21.

Next, after the hard mask 26 is removed, a conductive material made of, for example, titanium nitride is deposited on the entire surface, whereby the capacitor pillar 11 is embedded in the cylinders 31 and 32, as shown in FIG. 4J. At this time, the lower portion of the capacitor pillar 11 is connected to the pad electrode 19 shown in FIG. 1. Next, as shown in FIG. 4K, an unnecessary portion of titanium nitride formed on the top surface of the insulating film 25 is etched back, so that the capacitor pillars 11 are electrically isolated from each other. All the insulating films 21, 23, and 25 made of silicon oxide are then removed, so that a space is formed between the capacitor pillars 11. Thereafter, the capacitor dielectric film 12 is formed on the surface of the capacitor pillar 11, and the space is filled with the counter electrode 13. The semiconductor device shown in FIG. 1 is completed in this manner.

In the second embodiment, as described above, the cylinder 31 having a diameter of φ3 (>φ2) is filled with the insulating film 23 that can be easily etched, then the cylinder 32 having a diameter of φ2 is overlapped on the cylinder 31, and the insulating film 23 is etched via the cylinder 32. Accordingly, the cylinders 31 and 32 having a large aspect ratio as a whole can be easily formed. Furthermore, no interface is formed in the capacitor pillar 11 as in the first embodiment, and therefore a resistance value of the capacitor pillar 11 is also reduced.

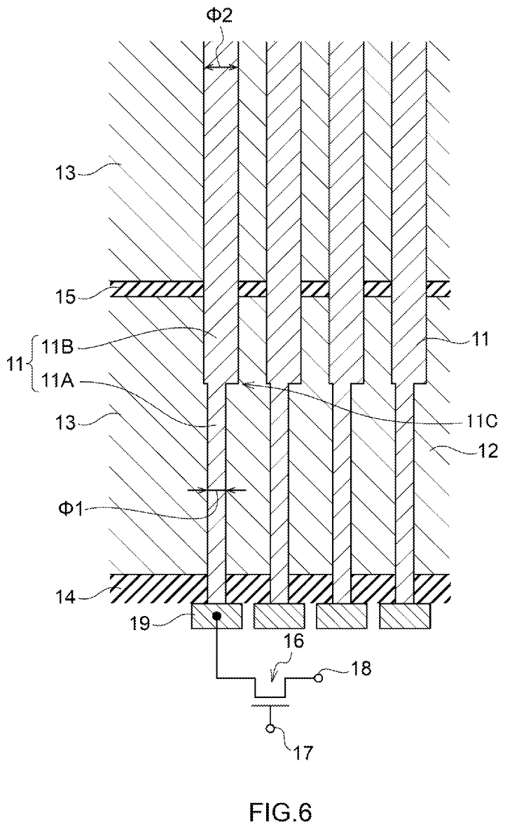

FIG. 6 is a schematic cross-sectional view showing a configuration of a main part of a semiconductor device according to another embodiment of the present disclosure. The semiconductor device shown in FIG. 6 is different from the semiconductor device shown in FIG. 1 in that the diameter φ1 of a lower region 11A of the capacitor pillar 11 is smaller than the diameter φ2 of an upper region 11B. The rest of the basic configuration of the semiconductor device is identical to that of the semiconductor device shown in FIG. 1, and thus like constituent elements are denoted by like reference signs and redundant explanations thereof are omitted. The capacitor pillar 11 has a stepped shape at a boundary position 11C between the lower region 11A and the upper region 11B. However, the capacitor pillar 11 has no interface at the boundary position 11C. The diameter of the lower region 11A at the boundary position 11C is smaller than the diameter of the upper region 11B at the boundary position 11C. As shown in FIG. 6, the height position of the beam 15 is higher than the boundary position between the lower region 11A and the upper region 11B. This configuration enables the upper region 11B to be supported by the beam 15.

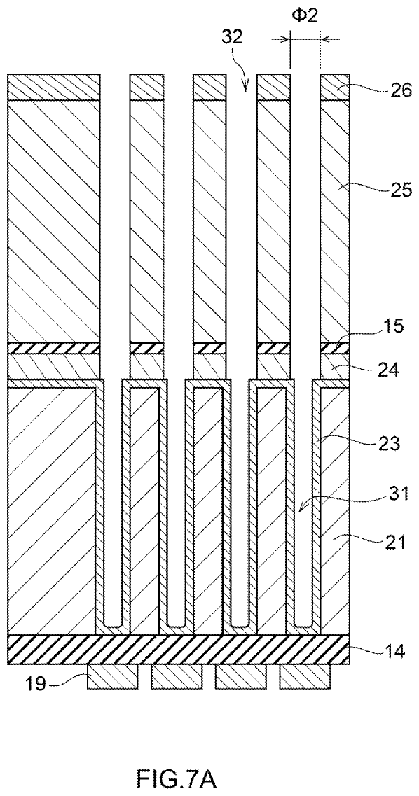

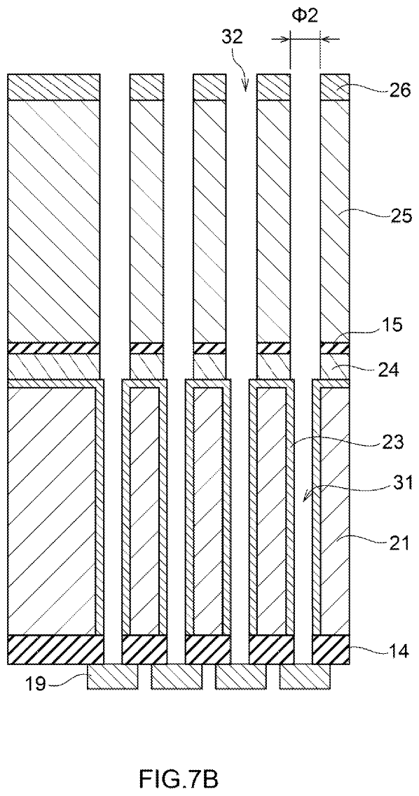

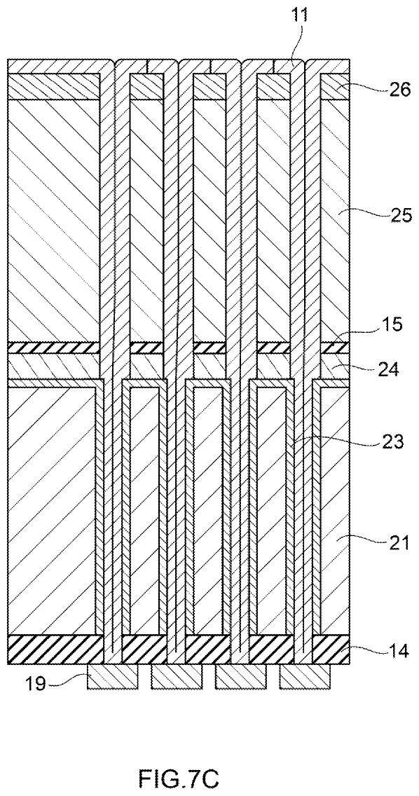

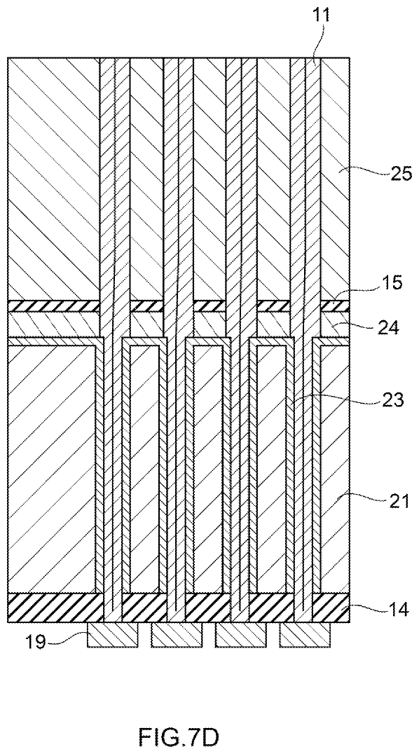

FIGS. 7A to 7D are process diagrams for explaining a manufacturing method of a semiconductor device according to a third embodiment of the present disclosure.

First, the processes shown in FIGS. 2A to 21 are performed. However, the insulating film 23 is replaced with a film 23 made of a material having a lower etching rate than the insulating film 21 in the present embodiment. Examples of the material of the film 23 include polysilicon and metal oxides. Thereafter, the insulating film 15 made of, for example, silicon nitride is etched as shown in FIG. 7A, and etching is further performed. In this manner, the insulating film 24 is removed at a position overlapped by the cylinder 32, whereas the film 23 is not etched and remains even at a position overlapped by the cylinder 32 because the etching rate of the film 23 is low in the present embodiment. Etching is further performed in this state, so that the pad electrode 19 is exposed, as shown in FIG. 7B.

Next, after the hard mask 26 is removed, a conductive material made of, for example, titanium nitride is deposited on the entire surface, so that the capacitor pillar 11 is embedded in the cylinders 31 and 32, as shown in FIG. 7C. At this time, a lower portion of the capacitor pillar 11 is connected to the pad electrode 19 shown in FIG. 6. Next, as shown in FIG. 7D, an unnecessary portion of titanium nitride formed on the top surface of the insulating film 25 is etched back, whereby the capacitor pillars 11 are electrically isolated from each other. The insulating films 21, 24, and 25 made of silicon oxide and the film 23 are then removed, so that a space is formed between the capacitor pillars 11. Subsequently, the capacitor dielectric film 12 is formed on the surface of the capacitor pillar 11, and the space is filled with the counter electrode 13. The semiconductor device shown in FIG. 6 is completed in this manner.

In the third embodiment, as described above, the film 23 made of a material having a lower etching rate than silicon oxide is used. Therefore, the diameter φ1 of the lower region 11A of the capacitor pillar 11 can be made smaller than the diameter φ2 of the upper region 11B. Accordingly, while a desired capacitance is ensured by the upper region 11B with a larger diameter, the capacitor pillar 11 and the pad electrode 19 can be surely overlapped each other due to the reduced diameter of the lower region 11A even when misalignment has occurred.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. A method comprising:
forming a first insulating film;
etching the first insulating film to form a first cylinder having a first diameter;
forming a second insulating film on the first insulating film;
etching the second insulating film to form a second cylinder overlapping the first cylinder and having a second diameter different from the first diameter;
etching the first insulating film overlapping the second cylinder;
filling the first and second cylinders with a conductive material; and
removing the first and second insulating films.

2. The method of claim 1, wherein the first diameter is smaller than the second diameter.

3. The method of claim 2, wherein the first cylinder completely overlaps the second cylinder.

4. The method of claim 2, wherein etching the first insulating film to form the first cylinder having the first diameter includes:
etching the first insulating film to form a third cylinder having a third diameter greater than the first diameter; and
forming a third insulating film on an inner wall of the third cylinder to form the first cylinder having the first diameter.

5. The method of claim 4, wherein the third diameter is substantially the same as the second diameter.

6. The method of claim 4, wherein the third insulating film is greater in an etching rate than the first insulating film in the third etching.

7. The method of claim 2, wherein the forming the second insulating film is performed so as not to fill the first cylinder.

8. The method of claim 2, further comprising:
forming a fourth insulating film on the first insulating film so as not to fill the first cylinder; and
forming a fifth insulating film on the fourth insulating film,
wherein the fifth insulating film is made of a different insulating material from the first, second, and fourth insulating films, and
wherein the second insulating film is formed on the fifth insulating film.

9. The method of claim 8,
wherein the first, second, and fourth insulating films are made of silicon oxide, and
wherein the fifth insulating film is made of silicon nitride.

10. The method of claim 8, wherein the removing is performed so as not to remove the fifth insulating film.

11. The method of claim 1, wherein the first diameter is greater than the second diameter.

12. The method of claim 11, wherein the second cylinder completely overlaps the first cylinder.

13. The method of claim 11, further comprising forming a third insulating film in the first cylinder before the forming the second insulating film.

14. The method of claim 13, wherein the first cylinder is filled with the third insulating film.

15. The method of claim 13, wherein the third insulating film is greater in an etching rate than the first insulating film in the third etching.

16. The method of claim 13, further comprising forming a fourth insulating film on the third insulating film,
wherein the fourth insulating film is made of a different insulating material from the first, second, and third insulating films, and
wherein the second insulating film is formed on the fourth insulating film.

17. The method of claim 16,
wherein the first, second, and third insulating films are made of silicon oxide, and
wherein the fourth insulating film is made of silicon nitride.

18. The method of claim 16, wherein the removing is performed so as not to remove the fourth insulating film.

19. A method comprising:
forming a first insulating film;
etching the first insulating film to form a first cylinder;
forming a second insulating film on an inner wall of the first cylinder to reduce a diameter of the first cylinder;
forming a third insulating film on the second insulating film so as not to fill the first cylinder;
etching the third insulating film to form a second cylinder overlapping the first cylinder and having a diameter greater than the first cylinder;
etching the second insulating film overlapping the second cylinder to enlarge a diameter of the first cylinder;
filling the first and second cylinders with a conductive material; and
removing the first, second, and third insulating films.

20. A method comprising:
forming a first insulating film;
etching the first insulating film to form a first cylinder;
filling the first cylinder with a second insulating film;
forming a third insulating film on the second insulating film;
etching the third insulating film to form a second cylinder overlapping the first cylinder and having a diameter smaller than the first cylinder,
etching the second insulating film overlapping the second cylinder;
filling the first and second cylinders with a conductive material; and
removing the first, second, and third insulating films.

21. An apparatus comprising:
a capacitor pillar including a lower section and an upper section;
a plate electrode covering an outer side surface of the capacitor pillar with an insulating film interposed therebetween; and
a pad electrode contacting a bottom surface of the lower section of the capacitor pillar,
wherein the capacitor pillar has a stepped shape such that a diameter of the lower section at a boundary between the lower section and the upper section is smaller than a diameter of the upper section at the boundary.
